(19) United States
(12) Patent Application Publication
(10) Pub. No.: US 2012/0212721 A1
(43) Pub. Date: Aug. 23, 2012

(54) SUBSTRATES AND MIRRORS FOR EUV MICROLITHOGRAPHY, AND METHODS FOR PRODUCING THEM

(75) Inventors: Wilfried CLAUSS, Ulm (DE); Martin WEISER, Sinsheim (DE)

(73) Assignee: CARL ZEISS SMT GMBH, Oberkochen (DE)

(21) Appl. No.: 13/399,615

(22) Filed: Feb. 17, 2012

Related U.S. Application Data
(63) Continuation of application No. PCT/EP2010/060165, filed on Jul. 14, 2010.
(60) Provisional application No. 61/234,815, filed on Aug. 18, 2009.

(51) Int. Cl. G03B 27/54; G03F 1/52

(52) U.S. Cl. 355/67; 430/4

(57) ABSTRACT

Mirrors having a reflecting coating for the EUV wavelength region and a substrate. A surface region of the substrate extends uniformly below the reflecting coating along this coating and, seen from the surface of the substrate, has a depth of down to 5 μm. Here, this surface region has a 2% higher density than the remaining substrate. Also disclosed are substrates that likewise have such surface regions and methods for producing such mirrors and substrates having such surface regions by irradiation using ions or electrons.

This application is a Continuation of International Application No. PCT/EP2010/060165, filed on Jul. 14, 2010, which claims the benefit under 35 U.S.C. 119(e)(1) of U.S. Provisional Application No. 61/234815, filed Aug. 18, 2009. The disclosures of these earlier applications are considered part of and are incorporated by reference in the disclosure of this application. A number of references are also incorporated herein by reference. In the event of an inconsistency between the explicit disclosure of the present application and the disclosures in the references or the earlier applications, the present application controls.

### FIELD AND BACKGROUND OF THE INVENTION

The present invention relates to mirrors that comprise substrates and a reflecting coating for the EUV wavelength region. Moreover, the invention relates to substrates for such mirrors, and to methods for producing such mirrors and substrates.

Different methods for treating materials and components with ion beams are known from the prior art. Thus, for example, it is known to use focused ion beams (FIBs) for imaging and regulating surfaces. Accelerating voltages for ions, such as gallium, for example, in the range from 5 to 50 kV and corresponding current intensities from 2 pA up to 20 nA are used for these methods. The ion beam can be focused with the aid of electrostatic lenses onto a diameter of a few nm and then be guided in linewise fashion over the surface by appropriate deflection.

The interaction of the ion beam with the surface gives rise to so-called sputtering processes that result in ability to treat materials on the nanometer scale.

However, because of the direct removal of the surface the field of use of this method cannot be used for topographic correction of optical elements, since local use of this method also changes the microroughness locally.

Moreover, by way of example it is known to use ion beam methods with relatively low acceleration energies, that is to say ions with energies in the range from 1.2 keV, for treating surfaces of optical elements such as, for example, lenses for objectives in microlithography. Use is made in this case of an accelerating voltage that is lower by comparison with the focused ion beam method, and so only a slight removal occurs directly in a layer from 1 to 2 nm on the surface. It is possible thereby for the microroughness of the surface to be maintained, and only topographic errors of larger dimension can be corrected. However, this method has a low efficiency because of the low removal rate. Moreover, the correction of topographic errors with a lateral extent in the range <1 mm is met here by difficulties with the positioning accuracy, since ions are difficult to focus in this energy range.

Also known, moreover, are high energy ion beam methods in which ions are implanted in components and/or materials with the aid of acceleration energies of up to 3 MeV or more. This method of ion implantation is mainly used in doping semiconductors.

Because of these various fields of use, the principles of the interaction of ion beams with materials have already been intensively investigated. It is known from these investigations that when striking the material the ions are braked by various braking mechanisms such as inelastic collisions with bound electrons, inelastic collisions with atomic nuclei, elastic collisions with bound electrons and elastic collisions with atomic nuclei etc. An overview of macroscopic and microscopic effects resulting therefrom on amorphous silicon dioxide is to be found, for example, in the publication by R. A. B. Devine in “Nuclear Instruments and Methods in Physics Research” B91 (1994) 378 to 390.

Furthermore, methods are known in which ion beams in the energy range of between 200 keV and 5 MeV are used to vary the topography or the refractive index of regions near the surface of a substrate by compacting the substrate material, see US20080149858.

Since microlithography will be dependent in future on the EUV wavelength region for a further rise in resolution, and since the mirrors thus coming into use are able to reflect only approximately 70% of the incident light owing to their coating, and consequently absorb approximately 30% of the incident light, materials with a low coefficient of thermal expansion must be used as substrate material for such mirrors. Such so-called “low expansion materials” are, for example, Zerodur®, ULE®, or Clearceram®. All these materials have a content of amorphous silicate glass above approximately 50%, in the extreme case even of 100%. It follows that the long term functionality of a projection exposure machine requires it to be ensured that the energy absorbed in the material during operation does not lead to changes in the substrate and thus to a degradation of the mirror surface. That is to say, it must be ensured that no sort of changes to the surface shape or roughness occur that can lead to an intolerable increase in the aberrations or the scattered light.

Amorphous silicon dioxide experiences a change in volume owing to the irradiation with high energy optical radiation, since the bonds are broken up locally by the input of energy and reformed anew in a geometrically changed way, and this leads to a compaction of the material. It is known that a change in volume induced by irradiation can amount to a few per cent of the volume within the depth of penetration reached by the radiation.

### OBJECTS AND SUMMARY OF THE INVENTION

It is an object of the invention to provide mirrors or substrates for mirrors for the EUV wavelength region that no longer exhibit any change in surface shape under EUV irradiation. It is also an object of the invention to provide corresponding methods for producing such mirrors or substrates. Moreover, another object of the invention is to provide a projection exposure machine for microlithography having such mirrors or substrates.

The inventors have found that, given intensive irradiation of light in the EUV wavelength range, amorphous silicon dioxide exhibits a similar saturation behavior with regard to the change in volume induced by irradiation, as the saturation behavior, known from the prior art, of amorphous silicon dioxide under particle irradiation using high energy ions or electrons. It is therefore proposed to undertake a change in volume in the case of a mirror or a substrate in accordance with the depth of penetration of light in the EUV wavelength region through initial damage and/or aging with ion or electron irradiation, the energy and the number of the ions and/or the electrons being selected such that the latter also result in correspondingly adequate initial damage and/or compaction to the depth of penetration.

This procedure has the advantage that simple and advantageous devices can be used for the electron or ion irradiation in order to cause initial damage to a mirror or a substrate, and that there is no need to make use of expensive EUV light sources to this end.

In one embodiment, seen from the surface down to a depth of down to 2 μm, a surface region of a mirror or a substrate is subjected to initial damage in such a way by the irradiation, resulting in a 3% higher density of the surface region by comparison with the remaining substrate.

In another embodiment, a surface region of a mirror or a substrate is initially damaged by the irradiation such that during a further irradiation with light in the EUV wavelength region with a dose of more than 10 kJ/mm², the mean reflection wavelength of the reflection spectrum of the mirror is displaced thereby by less than 0.25 nm, in particular less than 0.15 nm.

The mean reflection wavelength is understood as the wavelength of the centroid under the reflection curve plotted against the wavelength of a reflecting coating for the EUV wavelength region within the scope of this application.

The result of an inventive homogeneous irradiation with ions or electrons is that the surface shape of a mirror or of a substrate changes by less than 1 nm PV owing to the irradiation. This is achieved by virtue of the fact that along the surface to be irradiated the latter is uniformly irradiated such that each zone of the irradiated surface region experiences the same compaction. As a result, the surface is lowered overall, but its surface shape is not changed. In the case of ion beams, use is made for this purpose of ions with an energy of 0.2 to 10 MeV given total particle densities of 10¹⁴ to 10¹⁶ of irradiated ions per cm² substrate surface, and in the case of electron beams use is made of electrons with a dose of between 0.1 J/mm² and 2500 J/mm², preferably between 0.1 J/mm² and 100 J/mm², and even with higher preference between 0.1 J/mm² and 10 J/mm² given energies of 10 to 80 keV.

Within the scope of this application, a PV value is understood as the absolute difference between the maximum value and the minimum value of the difference between two surface shapes that are being compared with one another.

An inventive initially damaged or compacted mirror is not subjected under further EUV irradiation with a dose of more than 1 kJ/mm² to any further significant change in its surface shape, and so the latter deviates by less than 5 nm PV by comparison with the surface shape before the EUV irradiation. In particular, this change is less than 2 nm PV given a dose of approximately 0.1 kJ/mm².

The invention is based, furthermore, on the fact that in the method for irradiating mirrors or substrates it is possible to treat the latter, according to the invention, using ion or electron beams between or after different application steps. Firstly, it is possible for the substrate, which is treated in pretreatment steps up to a deviation of 2 nm PV from a desired surface shape, to be irradiated after these pretreatment steps and subsequently to be provided with the desired surface shape and/or polished quality in a final treatment step. Secondly, it is possible to irradiate the already finally treated and coated mirror for an adequate homogeneous initial damage using ions or electrons.

Use may be made here of ion beams with an energy of between 0.2 and 10 MeV given total particle densities of 10¹⁴ to 10¹⁶ of irradiated ions per cm² substrate surface, preferably during the treatment of the substrates before the final treatment steps, since the ion irradiation leads to an increased roughening of the irradiated surfaces, and is therefore advantageous when a subsequently polishing step smooths the surface.

Electron beams with a dose of between 0.1 J/mm² and 2500 J/mm², preferably between 0.1 J/mm² and 100 J/mm², and even with higher preference between 0.1 J/mm² and 10 J/mm² given energies of 10 to 80 keV can be used for all stages in the production of a mirror for the EUV wavelength region, starting from the substrate up to the finally polished and coated mirror, for the purpose of adequately initially damaging and/or aging the surface region of the mirror or substrate. Here, the electron beams afford the advantage that a corresponding irradiation does not lead to damaging of the surface or to roughening of the surface.

In the case of these methods, it is firstly important here that the irradiation be performed uniformly such that the surface region is homogeneously compacted and the surface shape already obtained by the pretreatment steps is thereby maintained. Secondly, it is important that the irradiation steps be performed only after the pretreatment steps, since the irradiation steps are performed only in a surface region of a few μm depth, and such surface regions would otherwise be removed by the pretreatment steps for producing a surface shape. The alternative to this is for the substrate to be initially damaged and/or aged down to a large depth or completely using ion or electron beams, leads to long and costly treatment processes.

Further advantageous embodiments of the inventive method of this invention include the above specified features of the embodiments of the inventive mirrors and/or substrates.

Also, further advantageous embodiments of the invention are given by the features of the dependent claims.

### BRIEF DESCRIPTION OF THE DRAWINGS

Further advantages, characteristics and features will become clear in the following detailed description of an exemplary embodiment with the aid of the attached drawings, of which, in a purely schematic way,

FIG. 1 shows the diagram of a device that can be used for the inventive method;

FIG. 2 shows a schematic of the uniformly irradiated surface region of a substrate;

FIG. 3 shows the representation of measured values with regard to the compaction of substrate material under intensive EUV irradiation;

FIG. 4 shows the representation of measured values with regard to the compaction of substrate material under intensive ion radiation; and

FIG. 5 shows the representation of measured values with regard to the compaction of substrate material under intensive electron irradiation.

### DETAILED DESCRIPTION

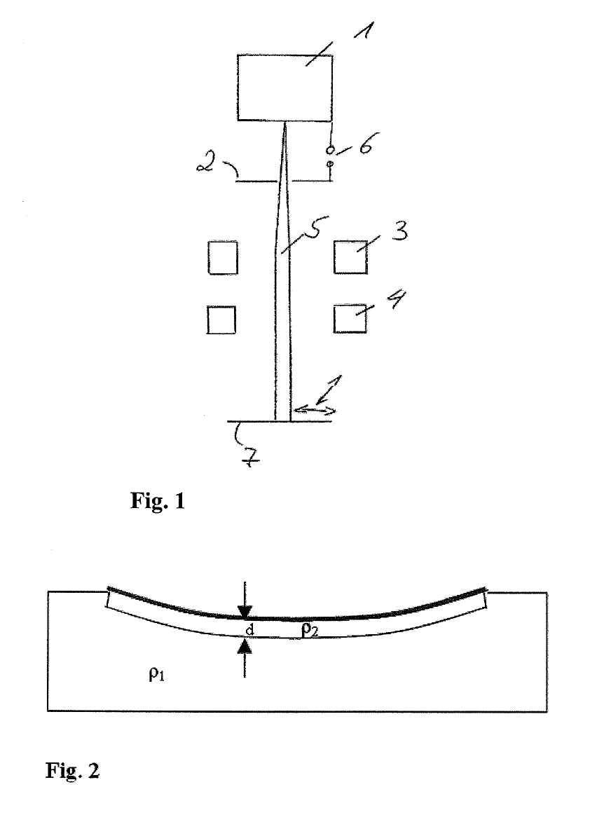

FIG. 1 shows a device for carrying out the inventive method in a schematic. Ions or electrons that are accelerated onto an aperture plate 2 via a voltage appropriately applied using a voltage source 6 are generated in an ion or electron source 1. An ion beam or electron beam optical system 3 that is constructed from suitable electrical and/or magnetic components can be used to focus the ion or electron beam 5. The focused beam 5 can be deflected by a deflection unit 4, which has, in turn, appropriate electrical and/or magnetic components, in two different directions that are illustrated by the double arrows. The ion or electron beam 5 can correspondingly be guided in a raster over the component 7 to be treated and/or handled, the ions interacting there with the material of the component 7 to be treated.

The generation of the ions or electrons in the ion or electron source 1, as well as a possible extraction of the ions or electrons by an electrostatic field and/or separation of the ions in accordance with their mass in a magnetic field can be carried out according to the known methods, and is not illustrated here and explained in more detail.

In accordance with an exemplary embodiment, use was made of a device illustrated in FIG. 1 to irradiate silicon ions with energies in the range from 500 to 2000 keV onto quartz. Given 700 keV Si ions, the range of the ions in the material was approximately 1 μm, the maximum range depending on the energy of the ions used with E^{2/3}. In the case of an irradiation with 10¹⁶ ions per cm², the physical material removal at the surface is 1 nm, while the effective surface lowering is about a few tens nm due to a change in the material structure in the braking region of the ions, see FIG. 4.

FIG. 2 shows a schematic of a substrate or a mirror comprising a substrate with a surface region, the surface region extending uniformly below the zone of the reflecting coating along this zone and, seen from the surface of the substrate, having a depth d of down to 5 μm. In this case, owing to an appropriate inventive homogeneous irradiation with ions or electrons the surface region has a density ρ₂ that is at least 2% higher than the density ρ₁ of the remaining substrate. The zone of the reflected coating is illustrated here as a finely dotted area.

In the braking region of the ions or electrons, the input of energy leads there in the surface region to an increase in the density and/or to compaction of amorphous silicon dioxide, as already mentioned at the beginning. This initial damage or aging preferably only in the region of the substrate that is also later exposed to EUV radiation prevents this region from being further changed by later EUV irradiation. As recognized in accordance with the invention, the reason for this is that all types of damage through ion, electron or EUV beams lead only to a certain degree of compaction and, moreover, in the event of further irradiation there is no further increase in this degree of compaction, which is denoted as saturation compaction within the scope of this application. Consequently, in the case of irradiation of a substrate with ions or electrons to irradiate uniformly in the surface region schematically illustrated in FIG. 2, and otherwise leaving the substrate unhandled, since only this surface region below the reflecting coating is exposed to the EUV radiation in later operation. In this case, the initial damage and/or aging of the surface region in FIG. 2 should be performed uniformly along the surface so that the entire surface region experiences a homogeneous compaction up to saturation compaction. Otherwise, nonuniform irradiation leads to an inhomogeneous initial damage in the surface region such that regions of the surface region which are not yet initially damaged or aged as far as saturation compaction are further changed up to saturation compaction in operation of the mirror by EUV radiation and thus lower the mirror surface in the regions affected, the result being that the surface shape of the mirror changes impermissibly during operation.

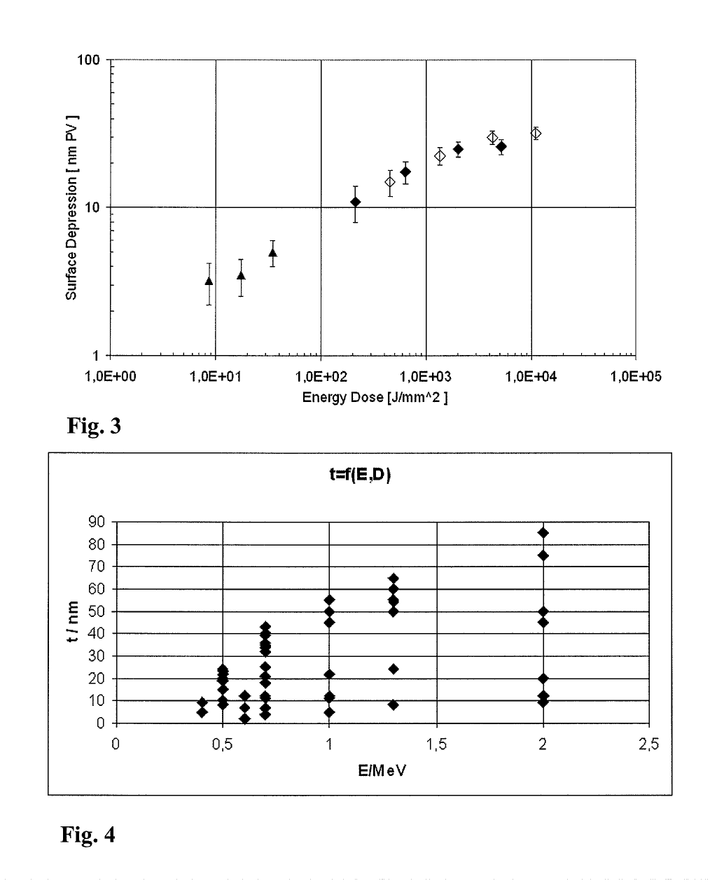

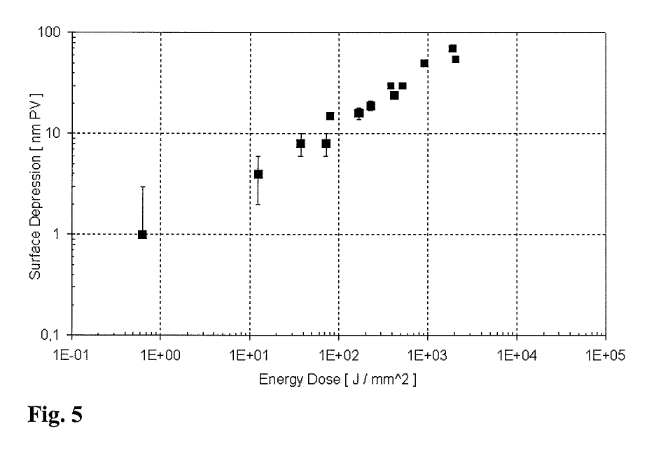

The initial damage and/or aging of the surface region of a substrate or a mirror with ion or electron beams should be performed in this case down to a depth that causes the substrate material to be compacted adequately as far as saturation compaction down to the depth of penetration of the later EUV irradiation. Here, this depth is a function of the energy of the ion or electron beams upon striking of the surface of the substrate or mirror, as already mentioned above. By contrast, until the saturation compaction is reached the degree of initial damage and/or aging is a function of the number of the total number of ions or electrons affected and the energy being output. A physical measure of this is the dose in the unit [J/mm²] with which a surface region is exposed to an ion or electron beam. FIGS. 3 and 5 show corresponding experimental data in the case of which the surface of a substrate or mirror is lowered, specified as a measure of the compaction of the surface region in the unit [nm], plotted against the dose of EUV irradiation (FIG. 3) and against the dose of electron beams (FIG. 5). The saturation compaction corresponds in this case to a saturation dose of the respective radiation, the saturation dose in the case of the EUV irradiation (FIG. 3) being approximately 10 kJ/mm².

FIG. 3 shows the compaction of substrate material from titanium-doped silica glass as squares, and from glass ceramic as triangles in the form of the lowering of the surface of irradiated surface regions in the unit [nm], plotted against the dose of EUV radiation in the unit [J/mm²]. The full and empty squares corresponds to different samples/measurements of silica glasses. It is to be seen that the lowering of the surface at a value of approximately 30 nm indicates a saturation behavior with the dose such that doses of more than 10 kJ/mm² do not lead to any further lowering of the surface by the compaction of the material lying therebelow on the basis of the EUV irradiation, since the above-described saturation compaction has already been reached at the dose of 10 kJ/mm².

FIG. 4 shows the compaction of substrate material in the form of the lowering of the surface of irradiated surface regions in the unit [nm], plotted against the energy of ion beams given various total particle densities of between 10¹⁴ and 10¹⁶ irradiated ions per cm² substrate surface. Here, the associated dose results correspondingly from the product of total particle density and energy of the ion beams. It is to be seen from FIG. 4 that only a specific lowering of the surface can be achieved depending on the dose for a given energy. For example, given an energy of 700 keV only a lowering of 45 nm can be achieved no matter how high the dose of ion radiation. This can be explained by the saturation compaction: after the latter has been achieved no further compaction results from an increase in the dose of ion beams. Consequently, with the aid of a specific dose of 700 keV of ion radiation it is possible already to achieve a saturation compaction that approximately corresponds to the saturation compaction illustrated in FIG. 3 on the basis of EUV irradiation. In this case, the saturation compaction of the 700 keV ion beams with a lowering of the surface by 45 nm may advance a little into more deeply lying regions than corresponds in the case of the saturation compaction of the EUV radiation with a lowering of approximately 30 nm. A 700 keV ion irradiation therefore accords with regard to the depth of damage a certain safety surplus by comparison with a later EUV irradiation. It is further to be seen with the aid of FIG. 4 that even in the case of high doses the lowering of the surface depends only on the energy of the ion radiation. This is associated with the fact that the energy of the ion radiation determines the depth of penetration thereof, as has already been explained, and that starting from a certain dose, further compaction beyond the saturation compaction is impossible, as has likewise already been explained above. Thus, it is only by the development of deeper lying surface regions using higher energy of the ion radiation that it is possible to bring about further compaction of these deeper lying regions if there is a desire for further lowering of the surface or compaction of the deeper lying regions.

FIG. 5 shows the compaction of substrate material made from titanium-doped silica glass in the form of the lowering of the surface of irradiated surface regions in the unit [nm], plotted against the dose of electron radiation in the unit [J/mm²]. It is to be seen that a lowering of the surface by 30 nm, which is sufficient for an inventive initial damage of the substrate or of the mirror, is reached in the case of a dose of approximately 500 J/mm². The energy of the electron beam can in this case be varied between 10 and 80 keV depending on the depth of penetration desired, as a result of which depths of penetration of down to 25 μm are then also covered. But even with a dose of electron radiation of about 10 J/mm² a lowering of the surface by more than 5 nm could be reached. Such a low dose of electron radiation reduces the radiation and production time and is high enough to protect by the induced compaction mirror substrates for EUV mirrors within EUV projection lenses, which will not receive too much EUV light. Due to the reflection losses within a EUV lithography apparatus such mirrors are situated more in the direction to the wafer than in the direction to the reticle within the projection lens.

The above description of various embodiments has been given by way of example. From the disclosure given, those skilled in the art will not only understand the present invention and its attendant advantages, but will also find apparent various changes and modifications to the structures and methods disclosed. It is sought, therefore, to cover all such changes and modifications as fall within the spirit and scope of the invention, as defined by the appended claims, and equivalents thereof.

1. A mirror comprising:
a reflecting coating, configured to reflect light from an extreme ultraviolet (EUV) wavelength region, and a substrate,
wherein the substrate has a surface region and a remaining region,
wherein the surface region of the substrate extends uniformly below the reflecting coating and along the reflecting coating and, when viewed from the surface of the substrate, has a depth of down to 5 μm, and
wherein the surface region has a 2% higher density than the remaining region.

2. The mirror according to claim 1, wherein the depth of the surface region of the substrate is larger than a depth of penetration of the light from the EUV wavelength region.

3. The mirror according to claim 1, wherein, when viewed from the surface of the substrate, the surface region of the substrate has a depth of down to 2 μm and a 3% higher density than the remaining region.

4. The mirror according to claim 1, wherein, when viewed from the surface of the substrate, the surface region of the substrate has a depth of down to 1 μm and a 4% higher density than the remaining region.

5. The mirror according to claim 1, wherein, after an irradiation with light from the EUV wavelength region with a dose of more than 10 kJ/mm², the mirror has a mean reflection wavelength within its reflection spectrum that deviates from the mean reflection wavelength before the irradiation by less than 0.25 nm.

6. The mirror according to claim 5, wherein the deviation in the mean reflection wavelength is less than 0.15 nm.

7. The mirror according to claim 1, wherein, after an irradiation with the light from the EUV wavelength region with a dose of more than 0.1 kJ/mm², the mirror has a surface shape that deviates by less than 2 nm PV from the surface shape before the irradiation.

8. The mirror according to claim 7, wherein, after a further irradiation with the light from the EUV wavelength region with a dose of more than 1 kJ/mm², the mirror has a surface shape that deviates by less than 5 nm PV from the surface shape after the first irradiation.

9. The mirror according to claim 1, wherein the higher density of the surface region results from a homogeneous irradiation of the substrate surface with ions having energies of between 0.2 MeV and 10 MeV given a total particle density of from 10¹⁴ to 10¹⁶ ions per cm², whereby the homogeneous irradiation changes a surface shape of the mirror by at most 1 nm PV.

10. The mirror according to claim 1, wherein the higher density of the surface region results from a homogeneous irradiation of the substrate surface with electrons having a dose of between 0.1 J/mm² and 2500 J/mm², given energies of between 10 and 80 keV, whereby the homogeneous irradiation changes a surface shape of the mirror by at most 1 nm PV.

11. The mirror according to claim 7, wherein the change in the surface shape is at most 0.5 nm PV.

12. A substrate for a mirror configured to reflect light from an extreme ultraviolet (EUV) wavelength region, said substrate comprising:
a surface region and a remaining region,
wherein, when viewed from the surface of the substrate, the surface region of the substrate extends uniformly below a zone for the reflecting EUV coating down to a depth of down to 5 μm, and has a 2% higher density than the remaining region.

13. The substrate according to claim 12, wherein the depth of the surface region of the substrate is greater than a depth of penetration of the light from the EUV wavelength region.

14. The substrate according to claim 12, wherein the surface region has a depth of down to 2 μm and a 3% higher density than the remaining region.

15. The substrate according to claim 12, wherein the surface region has a depth of down to 1 μm and a 4% higher density than the remaining region.

16. The substrate according to claim 12, wherein, after an irradiation with light from the EUV wavelength region with a dose of more than 0.1 kJ/mm², the substrate has a surface shape that deviates by less than 2 nm PV from the surface shape before the irradiation.

17. The substrate according to claim 12, wherein, after a further irradiation with the light from the EUV wavelength region with a dose of more than 1 kJ/mm², the substrate has a surface shape that deviates by less than 5 nm PV from the surface shape after the first irradiation.

18. The substrate according to claim 12, wherein the higher density of the surface region results from a homogeneous irradiation of the substrate surface with ions having energies of between 0.2 MeV and 10 MeV given a total particle density of from 10¹⁴ to 10¹⁶ ions per cm², whereby the homogeneous irradiation changes a surface shape of the substrate by at most 1 nm PV.

19. The substrate according to claim 12, wherein the higher density of the surface region results from a homogeneous irradiation of the substrate surface with electrons having a dose of between 0.1 J/mm² and 2500 J/mm², given energies of between 10 to 80 keV, whereby the homogeneous irradiation changes a surface shape of the substrate by at most 1 nm PV.

20. The substrate according to claim 16, wherein the change in the surface shape is at most 0.5 nm PV.

21. A method for producing a mirror comprising a reflecting coating, configured to reflect light from an extreme ultraviolet (EUV) wavelength region, and a substrate, said method comprising:
during a pretreatment, treating the substrate up to a deviation of 50 μm PV from a desired surface shape;
during an irradiation, irradiating the substrate treated in the pretreatment homogeneously over a prescribed zone of the reflecting coating with ions having an energy of between 0.2 MeV and 10 MeV given a total particle density of 10¹⁴ to 10¹⁶ ions per cm² or with electrons having a dose of between 0.1 J/mm² and 2500 J/mm², given energies of from 10 to 80 keV;
during a final treatment after the irradiation, providing the substrate surface a desired surface shape and polish quality; and
during a coating after the final treatment, providing the substrate with the reflecting coating for the EUV wavelength region.

22. A method for producing a substrate for a mirror comprising a reflecting coating configured to reflect light from an extreme ultraviolet (EUV) wavelength region,
said method comprising:
during a pretreatment, treating the substrate up to a deviation of 50 μm PV from a desired surface shape of the mirror, and
during an irradiation, irradiating the substrate treated in the pretreatment homogeneously over a prescribed zone of the reflecting coating with ions having an energy of between 0.2 MeV and 10 MeV given a total particle density of 10¹⁴ to 10¹⁶ ions per cm² or with electrons having a dose of between 0.1 J/mm² and 2500 J/mm² given energies of from 10 to 80 keV.

23. A method for producing a mirror comprising a reflecting coating, configured to reflect light from an extreme ultraviolet (EUV) wavelength region, and a substrate,
said method comprising:
during an irradiation, irradiating a mirror already provided with a reflecting coating for the EUV wavelength region homogenously over a zone of the reflecting coating with ions having an energy of between 0.2 MeV and 10 MeV given a total particle density of 10¹⁴ to 10¹⁶ ions per cm² or with electrons having a dose of between 0.1 J/mm² and 2500 J/mm² given energies of from 10 to 80 keV.

24. The method according to claim 21, wherein the homogeneous irradiation is carried out until a density is reached in a surface region that, when viewed from the surface of the substrate, extends uniformly below the zone of the reflecting coating down to a depth of down to 5 μm and wherein the surface region has a 2% higher density than the density of a remaining region, not including the surface region, of the substrate.

25. The method according to claim 24, wherein the depth of the surface region of the substrate is larger than a depth of penetration of the light from the EUV wavelength region.

26. The method according to claim 24, wherein, when viewed from the surface of the substrate, the surface region of the substrate has a depth of down to 2 μm and a 3% higher density than the remaining region.

27. The method according to claim 24, wherein, when viewed from the surface, the surface region of the substrate has a depth of down to 1 μm and a 4% higher density than the remaining region.

28. The method according to claim 21, wherein the homogeneous irradiation suffices for compacting a surface region of the substrate that, when viewed from the surface of the substrate, extends uniformly below the zone of the reflecting coating down to a depth of down to 5 μm, such that, after a further useful irradiation with light from the EUV wavelength region having a dose of more than 0.1 kJ/mm², the substrate has a surface shape that deviates by less than 2 nm PV from the surface shape before the useful irradiation.

29. The method according to claim 28, wherein, after a second useful irradiation with light from the EUV wavelength region having a dose of more than 1 kJ/mm², the substrate has a surface shape that deviates by less than 5 nm PV from the surface shape after the further useful irradiation.

30. The method according to claim 21, wherein the homogeneous irradiation changes a surface shape of the substrate by at most 1 nm PV during the irradiation.

31. The method according to claim 28, wherein the change in the surface shape is at most 0.5 nm PV.

32. A mirror comprising a substrate in accordance with claim 12, and a reflecting coating configured to reflect light from an extreme ultraviolet wavelength region.

33. A projection exposure machine for microlithography comprising a projection objective and an illumination system having at least one mirror in accordance with claim 1.
